(19) United States
(12) Patent Application Publication
(10) Pub. No.: US 2007/0163501 A1
(43) Pub. Date: Jul. 19, 2007

(54) Plasma processing apparatus

(75) Inventors: Tadahiro Ohmi, Miyagi (JP); Masaki Hirayama, Miyagi (JP); Tetsuya Goto, Miyagi (JP)

Correspondence Address: FOLEY AND LARDNER LLP;SUITE 500, 3000 K STREET NW, WASHINGTON, DC, 20007, US

(73) Assignee: Foundation for Advancement of International Science

(21) Appl. No.: 10/584,137

(22) PCT Filed: Dec. 24, 2004
(86) PCT No.: PCT/JP04/19318

§ 371 Date: Aug. 1, 2006

(30) Foreign Application Priority Data
Dec. 26, 2003 (JP) 2003-435508

(51) Int. Cl. C23F 1/00; C23C 16/00

(52) U.S. Cl. 118/723 MW; 156/345.34; 156/345.41; 156/914

(57) ABSTRACT

Plasma discharge occurs in the gas circulation space between the upper surface of a shower plate and the lower surface of a cover plate in partial contact with the shower plate, and the supplied microwave is uselessly consumed by this undesired discharge, thereby losing the power. A plasma processing apparatus comprises a shower plate having ejection holes for ejecting gas, a microwave antenna, and a cover plate interposed between the shower plate and the microwave antenna. The material of the cover plate has a relative dielectric constant smaller than that of the material of the shower plate.

### TECHNICAL FIELD

This invention relates to a plasma processing apparatus adapted to carry out treatments, such as CVD, etching such as RIE, ashing, oxidation, nitriding, and oxynitriding, on a processing object such as a semiconductor substrate or a liquid crystal display substrate, and a manufacturing method for manufacturing a product such as a semiconductor device by the use of the plasma processing apparatus, and in particular, relates to the structure of a cover plate in the plasma processing apparatus.

### BACKGROUND ART

Conventionally, as a microwave-excited high-density and low electron-temperature plasma processing apparatus, use has been made of a plasma processing apparatus as described in Patent Document 1. As described in Patent Document 1, this plasma processing apparatus comprises a radial line slot antenna adapted to radiate a microwave into a process chamber, a phase delay plate adapted to compress the wavelength of the microwave radiated from the antenna, an alumina cover plate disposed at an interval from the phase delay plate, and a shower plate. The shower plate which is usually made of a low-loss dielectric (alumina) and disposed immediately below the cover plate has a number of gas ejection holes. A gas for plasma generation is supplied to the gas ejection holes of the shower plate through a gas distribution space provided between an upper surface of the shower plate and a lower surface of the cover plate in partial contact with the shower plate. With this structure, when the microwave is applied in this state, a high-density plasma is generated in a space under a lower surface of the shower plate. This plasma is introduced to a process space where a processing object, for example, a semiconductor wafer, is processed.

In this case, the shower plate is provided with a plasma gas supply passage communicating with a plasma gas supply port formed in an outer wall of the process chamber and, from the plasma gas supply port, the plasma-exciting gas such as Ar or Kr is fed to the supply passage in the shower plate. Further, the exciting gas is introduced into the process chamber through the supply passage and the gas ejection holes of the shower plate.

In the foregoing plasma processing apparatus having the radial line slot antenna, a uniform high-density plasma is formed in the space immediately below the shower plate. The high-density plasma thus formed has a low electron temperature and hence no damage is caused occur to the processing substrate and no metal contamination occurs due to sputtering of the wall of the process container.

Patent Document 1:

Japanese Unexamined Patent Application Publication No. 2002-299330

### DISCLOSURE OF THE INVENTION

### Problem to be Solved by the Invention

According to the study of the present inventors, it has been found out that, in the foregoing conventional plasma processing apparatus, plasma discharge undesirably occurs in the gas distribution space between the upper surface of the shower plate and the lower surface of the cover plate partially contacted with the shower plate and hence the supplied microwave is wasted due to this undesired discharge to lose the power. This makes primary plasma discharge inefficient. Then, the present inventors have elucidated that this undesired discharge is caused by occurrence of electric field concentration in the foregoing gas distribution space and this electric field concentration results from a high relative dielectric constant of a material of the cover plate. In the conventional plasma processing apparatus, alumina is used for both the shower plate and the cover plate. The relative dielectric constant (Er) of alumina is approximately 9 (9.8 at 13.56 MHz and 8.8 at 2.45 GHz) while the relative dielectric constant of the gas in the gas distribution space is approximately 1. Therefore, the difference in relative dielectric constant is large and this causes the electric field concentration.

An object of this invention is to provide, based on the foregoing new knowledge in the plasma processing apparatus, a technique that can suppress undesired discharge.

A specific object of this invention is to provide a plasma processing apparatus or a semiconductor manufacturing apparatus that is excellent in microwave power efficiency.

Another object of this invention is to provide a method of manufacturing a product by the use of the foregoing plasma processing apparatus.

### MEANS FOR SOLVING THE PROBLEM

According to an aspect of the present invention, there is provided a plasma processing apparatus which comprises a shower plate having a plurality of ejection holes for ejecting a gas, a microwave antenna, and a cover plate interposed between said shower plate and said microwave antenna and which is characterized in that said cover plate is formed by a material which has a relative dielectric constant smaller than that of a material of said shower plate. The material of said cover plate is smaller in the relative dielectric constant and is larger in thermal conductivity as compared with the material of said shower plate. It is further preferable that the dielectric loss of the material be 1×10⁻⁴ or less.

The material of the cover plate is preferably formed by silicon nitride because its relative dielectric constant is 7.9. More preferably, quartz is used because its relative dielectric constant is 3.8. By mixing both materials or adding another material to them, it is also possible to obtain a material having a small relative dielectric constant, a large thermal conductivity, and a dielectric loss of 1×10⁻³ or less in microwave. In addition, it is to be noted that, while alumina has a thermal conductivity of 10⁻⁴, silicon nitride has that of 4×10⁻⁴ and aluminum nitride has that of 3.5×10⁻³.

According to another aspect of the present invention, there is provided a plasma processing apparatus which comprises a shower plate having a plurality of ejection holes for ejecting a gas, a microwave antenna, and a cover plate interposed between said shower plate and said microwave antenna, and which is characterized in that one of main surfaces of said cover plate comprises a plurality of projection-like portions contacted with said shower plate at portions at which no ejection holes are present on one of main surfaces of said shower plate and said projection-like portions are each formed by obtuse angles or a curved line when said one of main surfaces of said cover plate is seen from the above. Preferably, said projection-like portions each form a circle when said one of main surfaces of said cover plate is seen from the above. According to the present invention, there is provided a plasma processing apparatus which comprises a shower plate having a plurality of ejection holes for ejecting a gas, a microwave antenna, and a cover plate interposed between said shower plate and said microwave antenna and which is characterized in that one of main surfaces of said cover plate comprises connected projection-like portions contacted with said shower plate at which no ejection holes are present on one of main surfaces of said shower plate and hollow-like portions other than said projection-like portions, and said hollow-like portions include a curved line portion connected to upper portions of said ejection holes at said one of main surfaces of said shower plate and a gas introducing portion for introducing the gas into said curved line portion. Preferably, said curved line portion of said hollow-like portions includes a plurality of ring-shaped portions forming concentric circles and said gas introducing portion of said hollow-like portions includes a linear portion connecting said ring-shaped portions.

According to the present invention, there is further provided a plasma processing apparatus which comprises a shower plate having a plurality of ejection holes for ejecting a gas, a microwave antenna, and a cover plate interposed between said shower plate and said microwave antenna and which is characterized by including a structure wherein one of main surfaces of said cover plate comprises at least one projection-like portion contacted with said shower plate at portions at which no ejection holes are present on one of main surfaces of said shower plate and a gas distribution portion that is not contacted with said portions and that forms a gas distribution space between itself and said one of main surfaces of said shower plate, and means for introducing the gas to said one of main surfaces of said shower plate in order to cause the gas to flow into said ejection holes of said shower plate introduces the gas to said gas distribution portion at said one of main surfaces of said cover plate from its peripheral portion.

Further, there is obtained a plasma processing method or a product manufacturing method for manufacturing a semiconductor device, a liquid crystal display device, or an organic EL display device, which is characterized by carrying out plasma processing using one of the foregoing plasma processing apparatuses.

### EFFECT OF THE INVENTION

As described above, according to this invention, it becomes possible to efficiently introduce the microwave into the process chamber.

### BRIEF DESCRIPTION OF THE DRAWINGS

FIG. 1 is a sectional view showing a schematic structure of a plasma processing apparatus according to a first embodiment of this invention.

FIG. 2 is a plan view showing the structure of a cover plate used in the first embodiment of this invention.

FIG. 3 is a sectional view showing a schematic structure of a plasma processing apparatus according to a second embodiment of this invention.

FIG. 4 is a plan view showing the structure of a cover plate used in the second embodiment of this invention.

FIG. 5 is a sectional view showing a schematic structure of a plasma processing apparatus according to a third embodiment of this invention.

FIG. 6 is a sectional view showing a schematic structure of a plasma processing apparatus according to a fourth embodiment of this invention.

FIG. 7 is a plan view showing the structure of a cover plate used in a fifth embodiment of this invention.

### DESCRIPTION OF SYMBOLS

1 exhaust port
2 process chamber
3 processing substrate
4 holding platform
5 gas ejection hole
6 plate-shaped shower plate
7 seal ring
8 cover plate
17 slit
18 wave delay plate
19 plate
20 coaxial waveguide

### BEST MODE FOR CARRYING OUT THE INVENTION

Hereinbelow, embodiments of this invention will be described with reference to the drawings.

### Embodiment 1

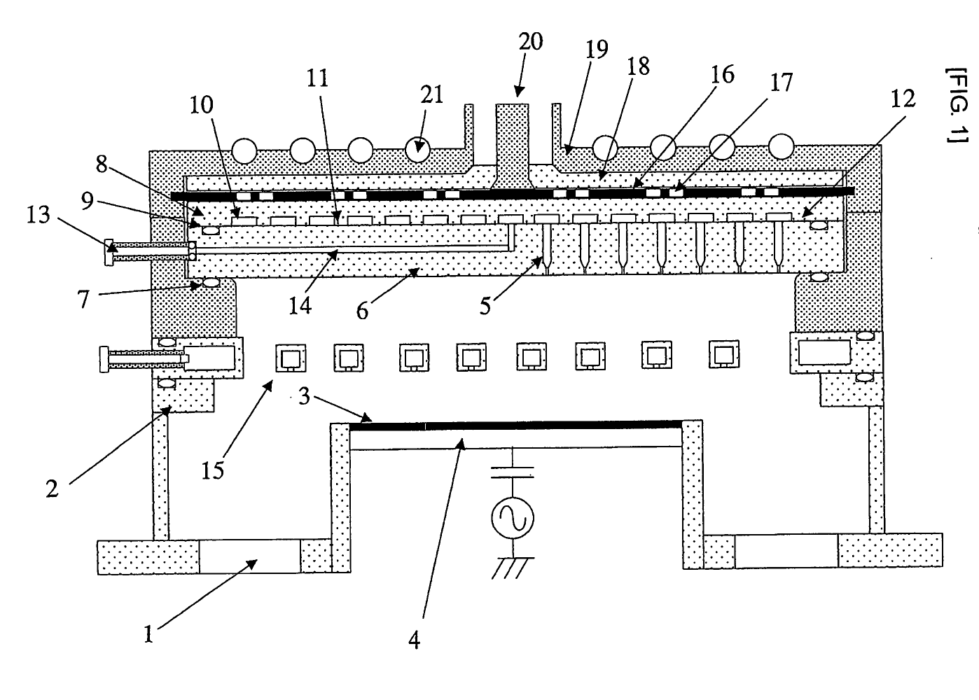

FIG. 1 shows the first embodiment. Referring to FIG. 1, there is shown a microwave plasma processing apparatus for Reactive Ion Etching (RIE) process. The illustrated microwave plasma processing apparatus has a process chamber 2 that is evacuated through a plurality of exhaust ports 1, and a holding platform 4 for holding a processing substrate 3 in the process chamber 2. In order to uniformly evacuate the process chamber 2, a ring-shaped space is defined around the holding platform 4 in the process chamber 2 and the plurality of exhaust ports 1 are arranged at equal or regular intervals, i.e. axisymmetrically to the processing substrate 3, so as to communicate with the space. By this arrangement of the exhaust ports 1, the process chamber 2 can be uniformly evacuated through the exhaust ports 1.

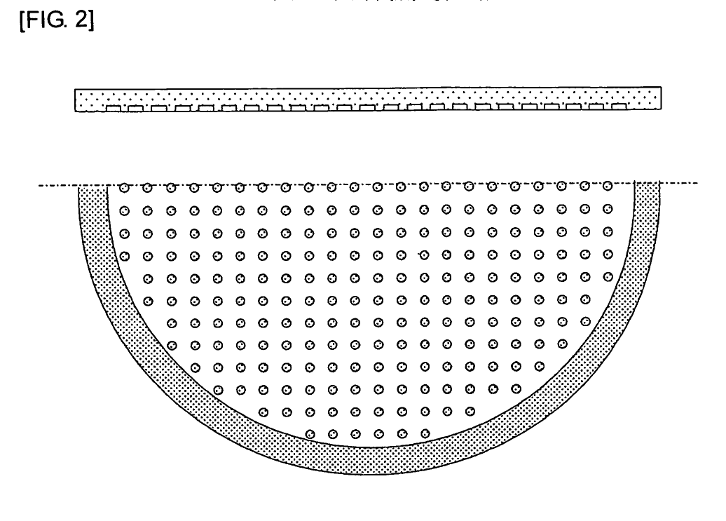

Over the process chamber 2, is mounted as part of an outer wall of the process chamber 2 through a seal ring 7, a plate-shaped shower plate 6 that is made of dielectric alumina with a relative dielectric constant of 9.8 and a low microwave dielectric loss (dielectric loss is 1×10⁻⁴ or less) and that has a number of opening portions, i.e. gas ejection holes 5 at a position corresponding to the processing substrate 3 on the holding platform 4. Further, over the process chamber 2, a cover plate 8 made of dielectric silicon nitride with a relative dielectric constant of 8, a relatively small microwave dielectric loss (dielectric loss is 3 ⁻⁴), and a high thermal conductivity (80 W/mK) is attached through another seal ring 9 on the outer side of the shower plate 6, i.e. on the side opposite to the holding platform 4 with respect to the shower plate 6. A space 10 for filling a plasma-exciting gas therein is formed between an upper surface of the shower plate and the cover plate 8. That is, in the cover plate 8, a number of projections 11 are formed on a surface of the cover plate 8 on the side of the shower plate 6 and further a projecting ring 12 is arranged around the cover plate 8 to be projected to a plane flush with the projections 11. Thus, the space 10 is formed between the shower plate 6 and the cover plate 8. The gas ejection holes 5 are communicated with the space 10. FIG. 2 shows a plan view of the cover plate 8 where the projections are arranged and its sectional view. The projections 11 each have a cylindrical shape with its diameter and height both of which are equal to 1.5 mm and 0.3 mm, respectively, and the interval between the projections is set to 5 mm. In FIG. 2, the diameter and the interval are shown in an enlarged fashion in order to avoid complexity.

Inside the shower plate 6, is formed a plasma-exciting gas supply passage 14 communicating with a plasma-exciting gas supply port 13 provided in the outer wall of the process chamber 2. The plasma-exciting gas such as Ar, Kr, or Xe supplied to the plasma-exciting gas supply port 13 is supplied to the gas ejection holes 5 from the supply passage 14 through the space 10 and introduced into the process chamber 2.

On a surface of the cover plate 8 opposite to its surface brought in contact with the shower plate 6, there is provided a radial line slot antenna adapted to radiate a microwave for plasma excitation. The radial line slot antenna is configured such that a wave delay plate 18 made of alumina is sandwiched between a copper plate 16 having a thickness of 0.3 mm and formed with a number of slits 17 and an aluminum plate 19 and, further, a coaxial waveguide 20 for supplying the microwave is disposed at the center. The microwave of 2.45 GHz generated by a microwave power supply (not shown) is supplied to the coaxial waveguide 20 through an isolator and a matching device (not shown either) and then is propagated while being radiated from the center toward the periphery in the wave delay plate 18 and through the slits 17 to the side of the cover plate 8. As a result, the microwave is substantially uniformly radiated to the side of the cover plate 8 through the number of slits 17. The radiated microwave is introduced into the process chamber 2 through the cover plate 6, the space 10 or the projections 11, and the shower plate 6 and ionizes the plasma-exciting gas, thereby generating a high-density plasma.

In this embodiment, the relative dielectric constant of the cover plate 8 is equal to 8 while the relative dielectric constant of the shower plate 6 is equal to 9.8. This shows that a rate of change in the relative dielectric constants through the space 10 specified by the relative dielectric constant of 1 is reduced as compared with the conventional example and hence the microwave electric field strength in the space 10 is reduced and, further, by forming the projections 11 into the cylindrical shape, no angular corners of the dielectric exist at convex portions in the space 10 so that local electric field concentration is suppressed. Therefore, abnormal discharge in the space 10 is suppressed, which enables efficient introduction of the microwave into the process chamber 2.

In the illustrated plasma processing apparatus, a conductor construction 15 is disposed between the shower plate 6 and the processing substrate 3 in the process chamber 2. This conductor construction 15 is provided with a number of nozzles for supplying a process gas from an external process gas source (not shown) through a process gas passage formed in the process chamber 2. The nozzles of the conductor construction 15 each eject the supplied process gas into an interspace between the conductor construction 15 and the processing substrate 3. The conductor construction 15 has opening portions between the adjacent nozzles. The opening portions each have a size to efficiently allow the plasma, excited by the microwave at a surface of the shower plate 6 on the side of the conductor construction 15, to pass into the interspace between the processing substrate 3 and the conductor construction 15 by diffusion.

When the process gas is ejected into the interspace from the conductor construction 15 having such a structure through the nozzles, the ejected process gas is excited by the plasma flowing into the interspace. However, since the plasma-exciting gas from the shower plate 6 flows toward the interspace between the conductor construction 15 and the processing substrate 3 from the space between the shower plate 6 and the conductor construction 15, components of the process gas that return to the space between the shower plate 6 and the conductor construction 15 are rare in amount. This is because decomposition of gas molecules due to excessive dissociation caused by exposure to the high-density plasma is small in amount and, further, even if the process gas is a depositional gas, a reduction in microwave introduction efficiency due to its deposition on the shower plate 6 or the like is hard to occur, which enables high-quality substrate processing.

### Embodiment 2

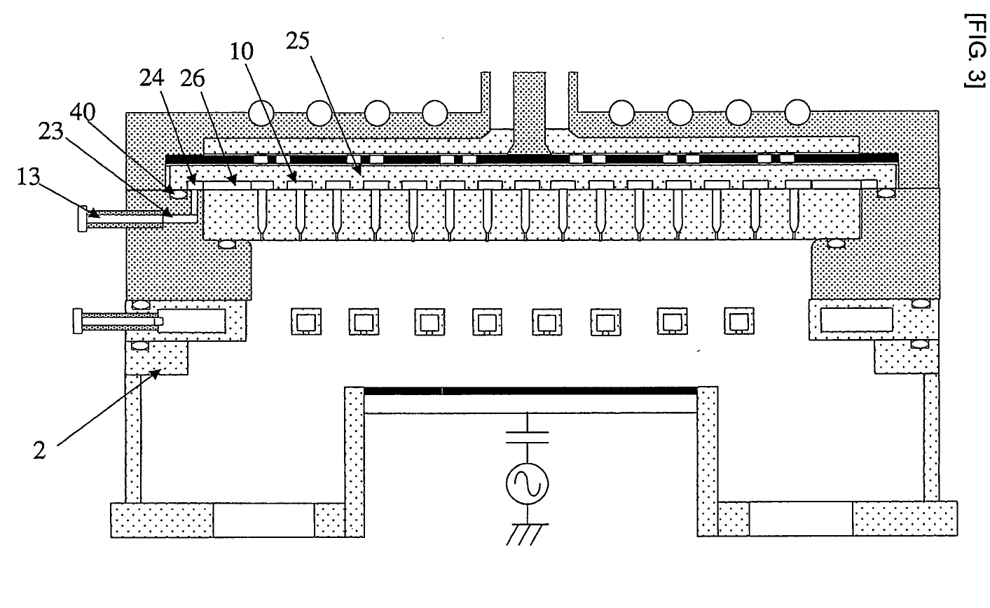

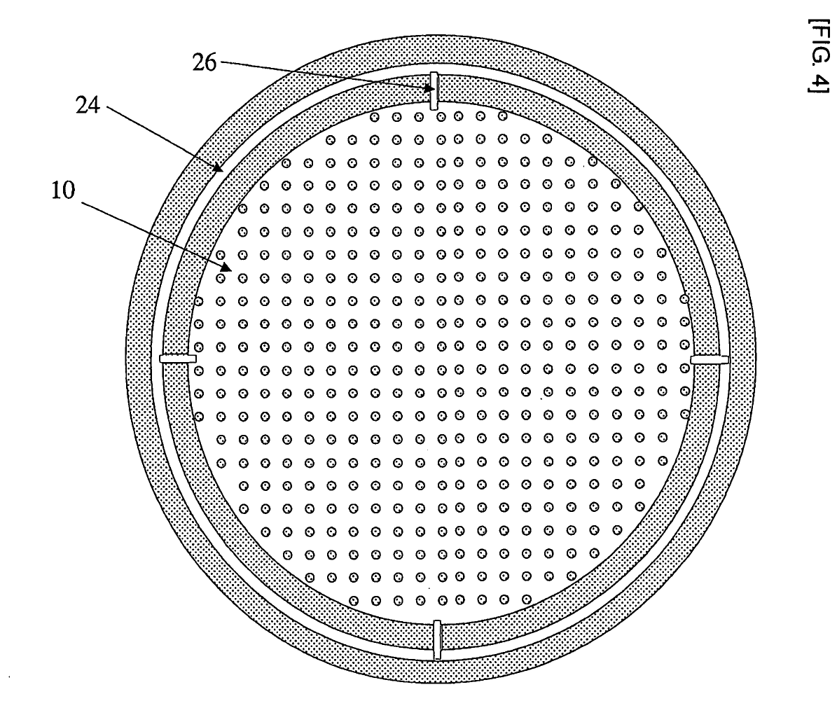

Referring to FIG. 3, there is shown a microwave plasma processing apparatus for Reactive Ion Etching (RIE) process. Description will be omitted about components that are similar in content to those of the first embodiment. Referring to FIG. 3, a cover plate 25 is attached to the process chamber 2 through a seal ring 40. A material of the cover plate 25 is formed by dielectric silicon nitride which has a relative dielectric constant of 8, a relatively small microwave dielectric loss (dielectric loss is 3×10⁻⁴), and a high thermal conductivity (80 W/mK). On the inner side of the seal ring 40, the cover plate 25 has a ring-shaped groove 24. The groove 24 has one or a plurality of grooves 26 which communicate with the space 10. A plasma-exciting gas supplied from the plasma gas supply port 13 is supplied to the groove 24 through a gas supply passage 23 and further introduced into the space 10 through the grooves 26. Further, the plasma-exciting gas is introduced into the process chamber 2 through the gas ejection holes 5 so that a high-density plasma is excited. FIG. 4 explains the cover plate 25 in more detail. The grooves 26 are axisymmetrically arranged at four positions. By providing the plurality of grooves in this manner, it is possible to uniformly supply the gas into the space 10 from the periphery of the cover plate 25. The grooves 26 each have a width of 2 mm and a depth of 0.3 mm and the groove 26 each have a width of 2 mm and a depth of 0.3 mm. In this embodiment, the grooves 26 are axisymmetrically arranged at the four positions but may not be limited to this number.

### Embodiment 3

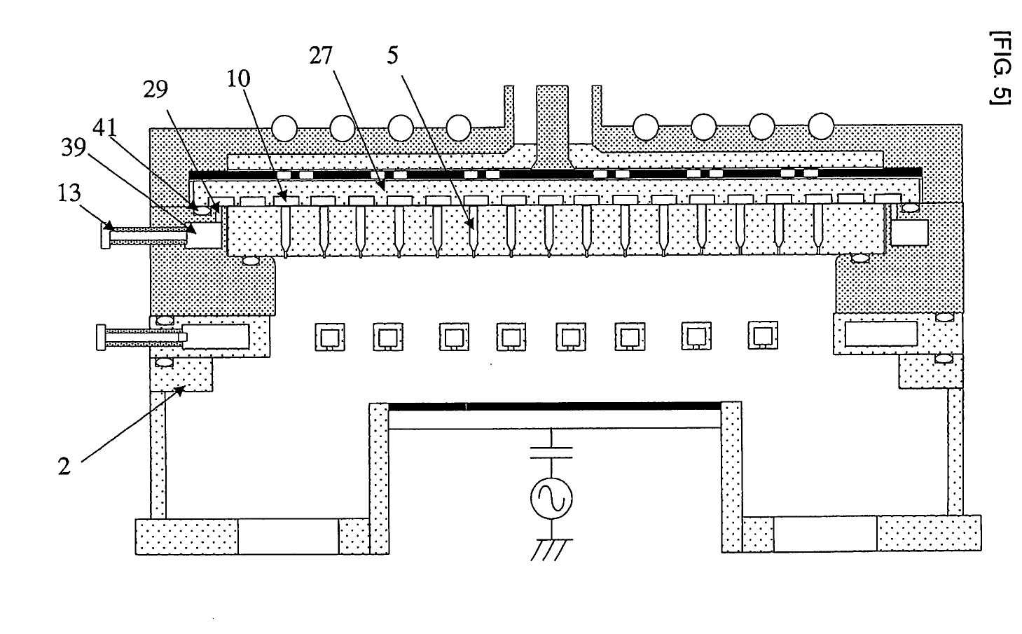

Referring to FIG. 5, there is shown a microwave plasma processing apparatus for Reactive Ion Etching (RIE) process. Description will be omitted about those that are similar in content to the first embodiment or the second embodiment. Referring to FIG. 5, a cover plate 27 is attached to the process chamber 2 through a seal ring 41. A material of the cover plate 27 is formed by dielectric silicon nitride which has a relative dielectric constant of 8, a relatively small microwave dielectric loss (dielectric loss is 3×10⁻⁴), and a high thermal conductivity (80 W/mK). A plasma-exciting gas supplied from the plasma-exciting gas supply port 13 is introduced into a ring-shaped space 39 provided inside the outer wall of the process chamber 2. The ring-shaped space 39 has an inner diameter of 370 mm, an outer diameter of 400 mm, and a height of 15 mm. The plasma-exciting gas introduced into the ring-shaped space 39 is supplied to the space 10 through a plurality of plasma-exciting gas supply passages 29 provided to the cover plate 27 so as to communicate with the space 10 and then is introduced into the process chamber 2 through the gas ejection holes 5 so that a high-density plasma is excited.

### Embodiment 4

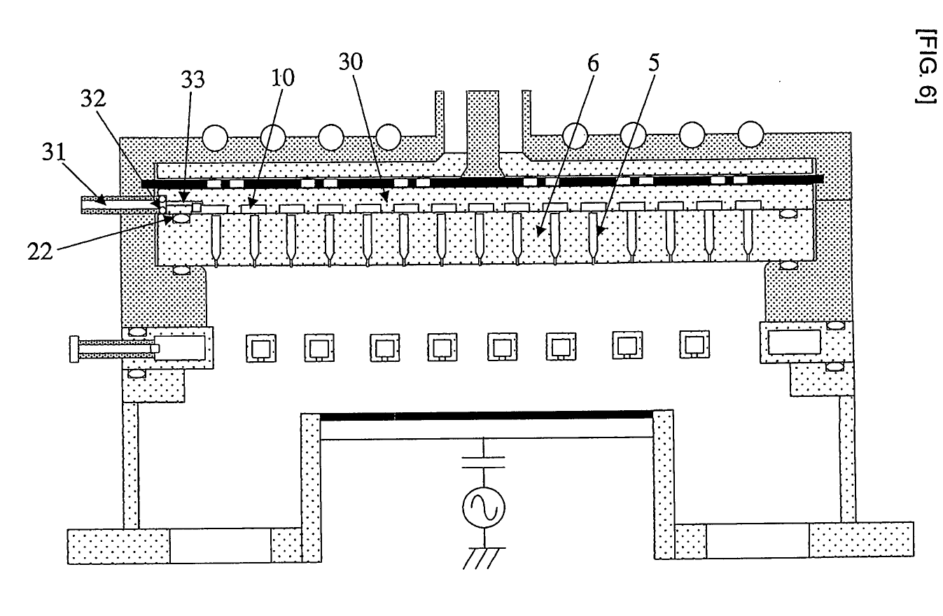

Referring to FIG. 6, there is shown a microwave plasma processing apparatus for Reactive Ion Etching (RIE) process. Description will also be omitted about those that are similar in content to the first embodiment, the second embodiment, or the third embodiment. Referring to FIG. 6, a cover plate 30 is attached to the process chamber 2 through a seal ring 22. A material of the cover plate 30 is formed by dielectric silicon nitride which has a relative dielectric constant of 8, a relatively small microwave dielectric loss (dielectric loss is 3×10⁻⁴), and a high thermal conductivity (80 W/mK). A plasma-exciting gas supply port 31 is connected to an outer peripheral portion of the cover plate 30 through a seal ring 32. Further, a gas supply hole 33 is provided in the cover plate 30 so as to establish communication between the space 10 and the plasma gas supply port 31. In order to carry out uniform gas supply, it is preferable that a plurality of plasma-exciting gas supply ports 31 and a plurality of plasma-exciting gas supply holes 33 are provided. In this embodiment, they are axisymmetrically arranged at four positions (only one position is shown). A plasma-exciting gas is filled into the gas ejection holes from the plasma gas supply ports 31 through the supply holes 33. The filled plasma-exciting gas is introduced into the process chamber 2 through the gas ejection holes 5 so that a high-density plasma is excited.

### Embodiment 5

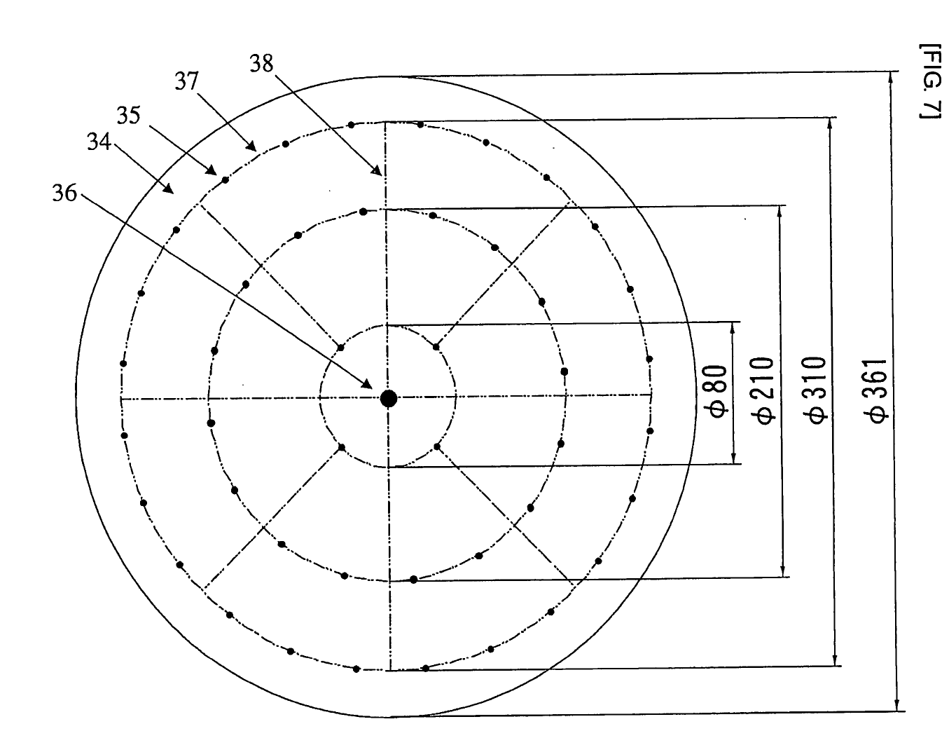

Referring to FIG. 7, there is shown the groove structure of a cover plate 34 according to the fifth embodiment. A material of the cover plate 34 is formed by dielectric silicon nitride which has a relative dielectric constant of 8, a relatively small microwave dielectric loss (dielectric loss is 3×10⁻⁴), and a high thermal conductivity (80 W/mK). In the figure, points 35 on the cover plate 34 indicate positions corresponding to the positions of the gas ejection holes provided in the shower plate opposed to the cover plate 34. A point 36 indicates a position corresponding to an outlet of the plasma-excited gas supply passage 14 provided in the shower plate. The shower plate has the gas ejection holes concentrically arranged in the shower plate, while, the cover plate 34 has grooves 37 on the corresponding circumferences. Four grooves 38 are formed radially from the center of the cover plate 34 where the gas is supplied, so as to supply the plasma-exciting gas to the concentric grooves 37. The grooves are each set to a width of 2 mm and a depth of 0.3 mm. In order to suppress the electric field concentration, it is preferable that corners formed at a point of intersection between the grooves be rounded with a radius of approximately 2. By introducing the groove structure only at the positions corresponding to the gas ejection holes of the shower plate, the gas filling space formed between the shower plate and the cover plate is minimized to reduce a change of the effective dielectric constant at the contact surfaces of the shower plate and the cover plate 34, thereby enabling efficient introduction of the microwave into the process chamber 2.

1. A plasma processing apparatus comprising a shower plate having a plurality of ejection holes for ejecting a gas, a microwave antenna, and a cover plate interposed between said shower plate and said microwave antenna, said plasma processing apparatus being characterized in that said cover plate is formed by a material which has a relative dielectric constant smaller than that of a material of said shower plate.

2. A plasma processing apparatus according to claim 1, characterized in that the material of said cover plate is smaller in the relative dielectric constant and is larger in thermal conductivity as compared with the material of said shower plate.

3. A plasma processing apparatus according to claim 2, characterized in that the material of said cover plate is smaller in the relative dielectric constant and larger in the thermal conductivity as compared with the material of said shower plate and further has a dielectric loss of 1×10⁻³ or less in microwave.

4. A plasma processing apparatus according to claim 1, characterized in that the material of said cover plate contains at least one of silicon nitride and quartz and the material of said shower plate contains alumina.

5. A plasma processing apparatus comprising a shower plate having a plurality of ejection holes for ejecting a gas, a microwave antenna, and a cover plate interposed between said shower plate and said microwave antenna, said plasma processing apparatus characterized in that one of main surfaces of said cover plate comprises a plurality of projection-like portions contacted with said shower plate at portions at which no ejection holes are present on one of main surfaces of said shower plate and said projection-like portions are each formed by obtuse angles or a curved line when said one of main surfaces of said cover plate is seen from the above.

6. A plasma processing apparatus according to claim 5, characterized in that said projection-like portions each form a circle when said one of main surfaces of said cover plate is seen from the above.

7. A plasma processing apparatus comprising a shower plate having a plurality of ejection holes for ejecting a gas, a microwave antenna, and a cover plate interposed between said shower plate and said microwave antenna, said plasma processing apparatus characterized in that one of main surfaces of said cover plate comprises connected projection-like portions contacted with said shower plate at which no ejection holes are present on one of main surfaces of said shower plate and hollow-like portions other than said projection-like portions, and said hollow-like portions include a curved line portion connected to upper portions of said ejection holes at said one of main surfaces of said shower plate and a gas introducing portion for introducing the gas into said curved line portion.

8. A plasma processing apparatus according to claim 7, characterized in that said curved line portion of said hollow-like portions includes a plurality of ring-shaped portions forming concentric circles and said gas introducing portion of said hollow-like portions includes a linear portion connecting said ring-shaped portions.

9. A plasma processing apparatus comprising a shower plate having a plurality of ejection holes for ejecting a gas, a microwave antenna, and a cover plate interposed between said shower plate and said microwave antenna, said plasma processing apparatus characterized by including a structure wherein one of main surfaces of said cover plate comprises at least one projection-like portion contacted with said shower plate at portions at which no ejection holes are present on one of main surfaces of said shower plate and a gas distribution portion that is not contacted with said portions and that forms a gas distribution space between itself and said one of main surfaces of said shower plate, and means for introducing the gas to said one of main surfaces of said shower plate in order to cause the gas to flow into said ejection holes of said shower plate introduces the gas to said gas distribution portion at said one of main surfaces of said cover plate from its peripheral portion.

10. A plasma processing method characterized by carrying out plasma processing using the plasma processing apparatus according to any one of claims 1, 5 or 9.

11. A semiconductor manufacturing method characterized by carrying out plasma processing using the plasma processing apparatus according to any one of claims 1, 5 or 9, thereby manufacturing a semiconductor device.

12. (canceled)

13. (canceled)

14. A method of manufacturing a liquid crystal display or an organic EL display, characterized by carrying out plasma processing using the plasma processing apparatus according to any one of claims 1, 5 or 9.
